(19) United States
(12) Patent Application Publication
(10) Pub. No.: US 2011/0057730 A1
(43) Pub. Date: Mar. 10, 2011

(54) RADIO FREQUENCY POWER AMPLIFIER

(75) Inventors: Satoshi MAKIOKA, Osaka (JP); Masahiko INAMORI, Osaka (JP)

(73) Assignee: PANASONIC CORPORATION, OSAKA (JP)

(21) Appl. No.: 12/873,538

(22) Filed: Sep. 1, 2010

(30) Foreign Application Priority Data
Sep. 4, 2009 (JP) 2009-205148

(51) Int. Cl. H03F 3/68

(52) U.S. Cl. 330/295

(57) ABSTRACT

To provide a multiband RF power amplifier which operates with improved isolation at multiple bands and in multiple modes in each of the bands.

An RF power amplifier according to an implementation of the present invention includes a first power amplifying circuit, a second power amplifying circuit, a third power amplifying circuit, and a fourth power amplifying circuit, and the first to the fourth power amplifying circuits each include, on a semiconductor substrate, an input pad for wire bonding, an input line, a power amplifier, an output line, and an output pad, and such input lines do not cross each other on chips, and such output lines do not cross each other on the chips.

### BACKGROUND OF THE INVENTION

(1) Field of the Invention

The present invention relates to a radio frequency (RF) power amplifier used for amplifying power of an RF signal, and relates particularly to a multiband and multimode RF power amplifier which is compatible with different frequency bands and different wireless communication modes.

(2) Description of the Related Art

To enable global utilization of a digital mobile terminal, a mobile terminal which is usable in a multiband frequency range (such as a range centering on 2 GHz and a range centering on 900 MHz) and a multimode system (such as Global System for Mobile Communications (GSM), Digital Communication system (DCS), and Universal Mobile Transmission Standard (UMTS)) is rapidly growing popular. Normally, in the configuration of a transmission power amplifier which amplifies a high-level output of electric power in the mobile terminal, a couple of semiconductor transistors for amplifying radio frequencies are connected in multiple stages. For compatibility with multiple bands and multiple modes, various power amplifiers and wireless communication devices using such power amplifiers have been considered (for example, see: Japanese Unexamined Patent Application Publication No. 2005-294894; and Japanese Unexamined Patent Application Publication No. 2003-174111).

Generally, the power amplifier outputs a transmission power in a wide range of: approximately +35 dBm in GSM mode, approximately +33 dBm in DCS mode, and approximately +27 dBm to −50 dBm in UMTS mode. Particularly, near +35 dBm (GSM), +33 dBm (DCS), and +27 dBm (UMTS) where the power output within the mobile terminal is maximum, the influence on the receiving unit becomes maximum in the mobile terminal. Accordingly, it is necessary to suppress the influence to the receiving unit.

A power amplifier for the mobile terminal which is compatible with multiple bands and multiple modes has a configuration in which plural RF transmission circuits including a power amplifier are connected in parallel so as to secure radio frequency characteristics. FIG. 7 shows a configuration of such a conventional RF power amplifier and a wireless communication device as described in Japanese Unexamined Patent Application Publication No. 2005-294894.

A wireless communication device 800 shown in FIG. 7 includes: a microphone 801; a speaker 806; an RF power amplifier 810; an antenna switch 813; an antenna 814; a Radio Frequency IC (RFIC) 815 which converts a baseband signal into an RF signal or converts an RF signal into a baseband signal; a baseband signal processing device 816; a duplexer 817a; filters 818a and 818b; matching circuits 820 and 821; a switch 830; filters 840b, 840c, 840d, and 840f; a gain control device 860; RF receiving circuit devices 8120 to 8122; and a transmission circuit 8130. Note that constituent elements enclosed by a dashed line constitute a first transmission path 8110, and a combination including filter 818a among a combination of constituent elements enclosed by an alternate long and short dash line constitutes a second transmission path 8111, and a combination including a filter 818b among a combination of constituent elements enclosed by an alternate long and short dash line constitutes a third transmission path 8112. In this wireless communication device 800, the first transmission path 8110 including the duplexer 817a is used for communications in the UMTS mode (using, for example, 2 GHz band) in accordance with Code Division Multiple Access (CDMA) scheme; the third transmission path 8112 including the filter 818b and the second transmission path 8111 including the filter 818a are used, respectively, for communications in GSM mode (using, for example, 900 MHz band) and communications in Digital Communication System (DCS) mode (using, for example, 1.8 GHz band) in accordance with Time Division Multiple Access (TDMA) scheme.

In addition, downsizing and cost reduction is considered to be an important issue for the multiband and multimode mobile communications device, and in order to respond to this, in recent years, efforts have been made to share a single input path between frequency bands of two frequency ranges when the frequency bands of RF signals input from RFIC 815 into the RF power amplifier 810 are relatively close to each other (such as frequency bands of 2 GHz and 1.8 GHz, and frequency bands of 850 MHz and 900 MHz). For example, an approach of deleting, in FIG. 7, the filter 840c and sharing one input path for inputting the two RF signals from the RFIC 815 to the RF power amplifier 810 has been considered. In this case, although it is necessary to improve the performance of the RFIC 815, such a simplified interface between the RFIC 815 and the RF power amplifier 810 and the reduced number of terminals are expected to achieve improvements in size and costs. Thus, such a configuration can realize a wireless communication device which is compact, low cost, and capable of amplifying and transmitting electric power in response to multiple bands and multiple modes.

### SUMMARY OF THE INVENTION

FIG. 8 is a diagram showing, in the case of adding one path of UMTS mode (for example, 850 MHz band) to the conventional wireless communication device described above, an example configuration of an RF power amplifier which is provided between an output of the RFIC, and matching circuits and filters in the wireless communication device. In other words, this RF power amplifier amplifies an RF signal of 850 MHz band within a frequency range at a low frequency side; an RF signal of 900 MHz band within a frequency range at the low frequency side; an RF signal of 1.8 GHz band within a frequency range at a high frequency side; and an RF signal of 2 GHz band within a frequency range at the high frequency side. In addition, the RF power amplifier is compatible with UMTS mode and DCS mode in the frequency ranges at the low frequency side, and is compatible with UMTS mode and GSM mode in the frequency ranges at the high frequency side. That is, the RF power amplifier shown in FIG. 8 operates at plural frequency bands (multiband) and in plural modes (multimode) in each of the frequency bands. Note that the RF power amplifier 900 shown in the figure collectively includes one input terminal for adjacent frequency bands, and output terminals are provided for the respective modes and frequency bands.

The RF power amplifier 900 shown in the figure includes: power amplifiers 901, 902, 903, and 904; input terminals IN1 and IN2; output terminals OUT_A1, OUT_A2, OUT_B1, and OUT_B2.

The power amplifier 901 amplifies a signal of 2 GHz band in UMTS mode, the power amplifier 902 amplifies a signal of 850 MHz band in UMTS mode, the power amplifier 903 amplifies a signal of 1.8 GHz band in DCS mode, and the power amplifier 904 amplifies a signal of 900 MHz band in GSM mode.

Of the RF signals input into the RF power amplifier 900, the signals of 2 GHz band and 1.8 GHz band which have frequency bands relatively close to each other are input into an input terminal IN1, and the signals of 850 MHz band and 900 MHz band are input into the input terminal IN2, irrespective of modes.

The RF signal of 2 GHz band in UMTS mode, which is input into the input terminal IN1, is amplified by the power amplifier 901 to be output at the output terminal OUT_A1. Likewise, the RF signal of 1.8 GHz band in DCS mode, which is input into the input terminal IN1, is amplified by the power amplifier 903, to be output at the output terminal OUT_B1. In addition, the RF signal of 900 MHz band in GSM mode, which is input into the input terminal IN2, is amplified by the power amplifier 904, to be output at the output terminal OUT_B2. Likewise, the RF signal of 850 MHz band in UMTS mode, which is input into the input terminal IN2, is amplified by the power amplifier 902, to be output at the output terminal OUT_A2.

As shown in FIG. 8, the output terminal OUT_A1 for outputting the RF signal of 2 GHz band in UMTS mode and the output terminal OUT_A2 for outputting the RF signal of 850 MHz band in UMTS mode are provided to be adjacent to each other or not to sandwich another output terminal in between, and the output terminal OUT_B1 for outputting the RF signal of 1.8 GHz band in DCS mode and the output terminal OUT_B2 for outputting the RF signal of 900 MHz band in GSM mode are provided to be adjacent to each other or not to sandwich another output terminal in between.

Here, an output line from the power amplifier 901 to the output terminal OUT_A1, an output line from the power amplifier 902 to the output terminal OUT_A2, an output line from the power amplifier 903 to the output terminal OUT_B1, and an output line from the power amplifier 904 to the output terminal OUT_B2 are laid out with sufficient isolation secured so as to prevent the lines from crossing each other.

By adapting the configuration and layout of the RF power amplifier 900 as described above, it is possible to collectively provide connections between the output terminal OUT_A1 and the duplexer and connections between the output terminal OUT_A2 and the duplexer on a board in the wireless communication device, thus realizing, using a simple layout, a compact and low-cost wireless communication device. In addition, it is also possible to collectively provide connections between the output terminal OUT_B1 and the filter and connections between the output terminal OUT_B2 and the filter on the board in the wireless communication device, thus realizing, using a simpler layout, the compact and low-cost wireless communication device.

In such a wireless communication device using this RF power amplifier 900, the RF signal of 2 GHz band in UMTS mode, which is output at the output terminal OUT_A1, is band-limited by the duplexer, to be transmitted from the antenna through the switch. The RF signal of 850 MHz band in UMTS mode, which is output at the output terminal OUT_A2, is band-limited by the duplexer, to be transmitted from the antenna 14 through the switch 13.

In addition, the RF signal of 1.8 GHz band in DCS mode, which is output at the output terminal OUT_B1, is band-limited by the filter, to be transmitted from the antenna through the switch. The GSM signal of 900 MHz band in GSM mode, which is output at the output terminal OUT_B2, is band-limited by the filter 818b, to be transmitted from the antenna through the switch.

As described above, in the RF power amplifier in the present example and the wireless communication device using the RF power amplifier, the line in UMTS mode from the duplexer does not cross the transmission path in GSM or DCS mode, thus avoiding a problem of deterioration of radio frequency characteristics such as deterioration of reception sensitivity of the receiving unit caused by the crossing of the transmission path in DCS mode and the reception path in UMTS mode from the duplexer, and achieving satisfactory wireless communication characteristics in small size at low cost.

In the RF power amplifier 900, the power amplifiers 901 to 904 include, on a semiconductor chip, a number of active elements such as transistors and passive elements such as resistors. Here, these active and passive elements, lines, and external connection pads are connected via lines each made of a metal or a low-resistant semiconductor that is doped with impurities at high level concentration, and so on. Such lines are formed by a multilayer wiring technique for the semiconductor. In addition, as represented by a crossing portion 911, each line in a portion where at least two lines cross each other is separated into upper and lower layers by, for example, a silicon dioxide film or silicon nitride film, so as to be insulated from each other.

However, coupling of electric signals occurs between upper and lower lines at the crossing portion 911 due to parasitic capacitance, causing an influence of the electric signals between lines which should be electrically independent, and such influence is mixed as noise. Particularly, the semiconductor chip dealing with the RF signal is subject to the influence of the RF signal propagated through another line, which influence grows larger as the frequency of the RF signal becomes higher, thus causing a problem of deterioration of electrical characteristics.

It is possible to give deterioration of isolation as an example of deterioration of electrical characteristics. Even in the configuration described above, isolation does not deteriorate for an RF signal at an intermediate frequency (IF) signal band that is a relatively low frequency band of 100 MHz or so, but the isolation deteriorates with an RF signal of 800 MHz or higher. A more serious problem is that the deteriorated isolation causes a load of the RF power amplifier in an off state to appear, resulting in impedance fluctuation and causing parasitic resonance.

An object of the present invention is to provide a multiband RF power amplifier which operates with improved isolation at multiple bands and in multiple modes in each of the bands.

To solve the problem described above, a radio frequency power amplifier according to an aspect of the present invention includes: a first power amplifying circuit which linearly amplifies a first radio frequency signal of a first frequency band; a second power amplifying circuit which linearly amplifies a second radio frequency signal of a second frequency band lower than the first frequency band; a third power amplifying circuit which nonlinearly amplifies a third radio frequency signal of the first frequency band; and a fourth power amplifying circuit which nonlinearly amplifies a fourth radio frequency signal of the second frequency band, and the first power amplifying circuit includes: a first input pad for wire bonding formed on a semiconductor substrate; a first input line formed on the semiconductor substrate and having one end connected to the first input pad; a first power amplifier formed on the semiconductor substrate and connected to the other end of the first input line; a first output line formed on the semiconductor substrate and having one end connected to the first power amplifier; and a first output pad formed on the semiconductor substrate and connected to the other end of the first output line, the second power amplifying circuit includes: a second input pad for wire bonding formed on the semiconductor substrate; a second input line formed on the semiconductor substrate and having one end connected to the second input pad; a second power amplifier formed on the semiconductor substrate and connected to the other end of the second input line; a second output line formed on the semiconductor substrate and having one end connected to the second power amplifier; and a second output pad formed on the semiconductor substrate and connected to the other end of the second output line, the third power amplifying circuit includes: a third input pad for wire bonding formed on the semiconductor substrate; a third input line formed on the semiconductor substrate and having one end connected to the third input pad; a third power amplifier formed on the semiconductor substrate and connected to the other end of the third input line; a third output line formed on the semiconductor substrate and having one end connected to the third power amplifier; and a third output pad formed on the semiconductor substrate and connected to the other end of the third output line, the fourth power amplifying circuit includes: a fourth input pad for wire bonding formed on the semiconductor substrate; a fourth input line formed on the semiconductor substrate and having one end connected to the fourth input pad; a fourth power amplifier formed on the semiconductor substrate and connected to the other end of the fourth input line; a fourth output line formed on the semiconductor substrate and having one end connected to the fourth power amplifier; and a fourth output pad formed on the semiconductor substrate and connected to the other end of the fourth output line, the first and second output pads are disposed next to each other, the third and fourth output pads are disposed next to each other, the first to fourth input lines do not cross each other on the semiconductor substrate, and the first to fourth output lines do not cross each other on the semiconductor substrate.

With this configuration, on the semiconductor substrate, no coupling of RF signals due to parasitic capacitance is caused between the first to fourth input lines and between the first to fourth output lines. As a result, the RF power amplifier according to the aspect of the present invention improves isolation, and can operate in multiple modes in each of the first and second frequency bands. In addition, the first to fourth input pads are for wire bonding, with which the first to fourth input pads can be easily connected to another pad by wire bonding, thus simplifying the circuit configuration.

Here, the first input pad may be wire-bonded to a first input unit which is provided on a board that is to be mounted with the radio frequency power amplifier and into which the first and third radio frequency signals are input, the second input pad may be wire-bonded to a second input unit which is provided on the board and into which the second and fourth radio frequency signals are input, the third input pad may be wire-bonded to the first input unit, and the fourth input pad may be wire-bonded to the second input unit.

With this configuration, it is possible to easily connect the first input unit and the second input unit, and the first to fourth input pads.

Here, the radio frequency power amplifier may include: a board; and the semiconductor substrate to be mounted on the board, and the board may include: a first line having one end connected to the first input unit; a first connection pad connected to the other end of the first line; a second line having one end connected to the first connection pad; a second connection pad connected to the other end of the second line; a third line having one end connected to the second input unit; a third connection pad connected to the other end of the third line; a fourth line having one end connected to the third connection pad; and a fourth connection pad connected to the other end of the fourth line, and the radio frequency power amplifier may further include: a first wire having one end bonded to the first input pad and the other end bonded to one of the first and second connection pads that is closer to the first wire; a second wire having one end bonded to the second input pad and the other end bonded to one of the third and fourth connection pads that is closer to the second wire; a third wire having one end bonded to the third input pad and the other end bonded to the other of the first and second connection pads that is closer to the third wire; and a fourth wire having one end bonded to the fourth input pad and the other end bonded to the other of the third and fourth connection pads that is closer to the fourth wire.

With this configuration, the first to fourth wires bonded to the first to fourth input pads cross, in the case of crossing the input lines, in an upper potion in a direction perpendicular to the input lines. Thus, compared to the case of lines crossing each other in outer and inner layers on a multilayer substrate made up of dielectrics, the RF power amplifier 100a according to the present embodiment has a small spatial permittivity between lines and thus allows securing a distance larger than an interlayer distance of the multilayer substrate. In addition, such bonding using wires allows securing a distance larger than an interlayer distance of the multilayer substrate. Accordingly, it is possible to improve isolation in the signal paths at an input side of the power amplifiers AMP1 to AMP4.

Here, the radio frequency power amplifier may include: a fifth wire having one end bonded to the first input unit and the other end bonded to one of the first and third input pads that is closer to the first input unit; and a sixth wire having one end bonded to the other of the first and third input pads and the other end bonded to the one of the first and third input pads connected to the first input unit.

Here, the radio frequency power amplifier may include: a seventh wire having one end bonded to the second input unit and the other end bonded to one of the second and fourth input pads that is closer to the second input unit; and an eighth wire having one end bonded to the other of the second and fourth input pads and the other end bonded to the one of the second and fourth input pads connected to the second input unit.

Here, the radio frequency power amplifier may include: a fifth wire having one end bonded to the first input unit and the other end bonded to one of the first and third input pads that is closer to the first input unit; a sixth wire having one end bonded to the other of the first and third input pads and the other end bonded to the one of the first and third input pads connected to the first input unit; a seventh wire having one end bonded to the second input unit and the other end bonded to one of the second and fourth input pads that is closer to the second input unit; and an eighth wire having one end bonded to the other of the second and fourth input pads and the other end bonded to the one of the second and fourth input pads connected to the second input unit.

With this configuration, since the lines on the board that are for connecting the input units and input pads are no longer necessary, it is possible to downsize the radio frequency power amplifier and to remove insertion loss that is caused when the RF signal is passing through the lines. In addition, for example, since this allows continuous bonding from the first input unit to the third input pad via the first input pad, it is possible to reduce the number of times of bonding. Accordingly, this increases productivity and cost advantages.

Here, at least one of the first to fourth input pads may be disposed closer to a corresponding one of the first to fourth power amplifiers than the others of the first to fourth input pads.

With this configuration, the wires bonded to the pads do not cross each other, thus facilitating the layout of each wire.

Here, one of the first to fourth input pads that is next to the at least one of the first to fourth input pads that is disposed closer to the corresponding one of the first to fourth power amplifiers may be disposed at a predetermined position on a line extended from the input line connected to the corresponding one of the first to fourth power amplifiers.

With this configuration, since a larger area can be secured for the input lines that constitute the impedance matching circuit, it is possible to achieve a multistage matching circuit with improved performance, thus reducing loss due to impedance mismatching with the RF signal, or increasing a gain of the power amplifier. In addition, since this reduces the distance between each input unit and each input pad, and thus reduces the length of the wire between the input pad and the wire, it is possible to reduce phase shift and insertion loss in the wire.

Here, the first input unit may be disposed equidistant from each of the first and third input pads.

Here, the second input unit may be disposed equidistant from each of the second and fourth input pads.

With this configuration, it is possible to reduce input impedance mismatching of the RF power amplifier in each mode at the same frequency band.

Here, the semiconductor substrate may include a first semiconductor chip and a second semiconductor chip, the first and second power amplifying circuits may be formed on the first semiconductor chip, and the third and fourth power amplifying circuits may be formed on the second semiconductor chip.

Here, the semiconductor substrate may include a first semiconductor chip, a second semiconductor chip, and a third semiconductor chip, the third and fourth power amplifying circuits may be formed on the first semiconductor chip, the first power amplifying circuit may be formed on the second semiconductor chip, and the second power amplifying circuit may be formed on the third semiconductor chip.

Here, the semiconductor substrate may include a first semiconductor chip, a second semiconductor chip, and a third semiconductor chip, the first and second power amplifying circuits may be formed on the first semiconductor chip, the third power amplifying circuit may be formed on the second semiconductor chip, and the fourth power amplifying circuit may be formed on the third semiconductor chip.

Here, the semiconductor substrate may include a first semiconductor chip, a second semiconductor chip, and a third semiconductor chip, the second and third power amplifying circuits may be formed on the first semiconductor chip, the first power amplifying circuit may be formed on the second semiconductor chip, and the fourth power amplifying circuit may be formed on the third semiconductor chip.

Here, the semiconductor substrate may include four semiconductor chips, and the first to fourth power amplifying circuits may be formed in the semiconductor chips different from each other.

Here, the semiconductor substrate may be a semiconductor chip.

Here, the third and fourth power amplifying circuits may be rotated to be disposed at a predetermined angle with respect to the first and second power amplifying circuits.

With this configuration, it is possible to downsize the RF power amplifier. In addition, by forming a desired RF power amplifying circuit on the same or a different semiconductor substrate, it is possible to reduce phase shift, insertion loss, or loss caused by impedance mismatching, thus forming the RF power amplifier with improved isolation.

According to the present invention, it is possible to provide an RF power amplifier which operates with improved isolation at multiple bands and in multiple modes in each of the bands.

### FURTHER INFORMATION ABOUT TECHNICAL BACKGROUND TO THIS APPLICATION

The disclosure of Japanese Patent Application No. 2009-205148 filed on Sep. 4, 2009 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 is a block diagram showing an example configuration of a wireless communication device;

FIG. 2A is a diagram showing an example circuit configuration and layout of the RF power amplifier according to a first embodiment;

FIG. 2B is a diagram showing an example circuit configuration and layout of the RF power amplifier according to the first embodiment;

FIG. 3A is a diagram showing an example circuit configuration and layout of the RF power amplifier according to a second embodiment;

FIG. 3B is a diagram showing an example circuit configuration and layout of the RF power amplifier according to the second embodiment;

FIG. 3C is a diagram showing an example circuit configuration and layout of the RF power amplifier according to the second embodiment;

FIG. 3D is a diagram showing an example circuit configuration and layout of the RF power amplifier according to the second embodiment;

FIG. 3E is a diagram showing an example circuit configuration and layout of the RF power amplifier according to the second embodiment;

FIG. 3F is a diagram showing an example circuit configuration and layout of the RF power amplifier according to the second embodiment;

FIG. 3G is a diagram showing an example circuit configuration and layout of the RF power amplifier according to the second embodiment;

FIG. 4A is a diagram showing an example circuit configuration and layout of the RF power amplifier according to a third embodiment;

FIG. 4B is a diagram showing an example circuit configuration and layout of the RF power amplifier according to the third embodiment;

FIG. 4C is a diagram showing an example circuit configuration and layout of the RF power amplifier according to the third embodiment;

FIG. 4D is a diagram showing an example circuit configuration and layout of the RF power amplifier according to the third embodiment;

FIG. 5 is a diagram showing an example circuit configuration and layout of the RF power amplifier according to a fourth embodiment;

FIG. 6 is a diagram showing an example circuit configuration and layout of the RF power amplifier according to a fifth embodiment;

FIG. 7 is a diagram showing an example circuit configuration of a conventional wireless communication device; and

FIG. 8 is a diagram showing an example configuration of the RF power amplifier in the case of further adding one path in UMTS mode (for example, 850 MHz band) to the conventional wireless communication device.

### DESCRIPTION OF THE PREFERRED EMBODIMENTS

### First Embodiment

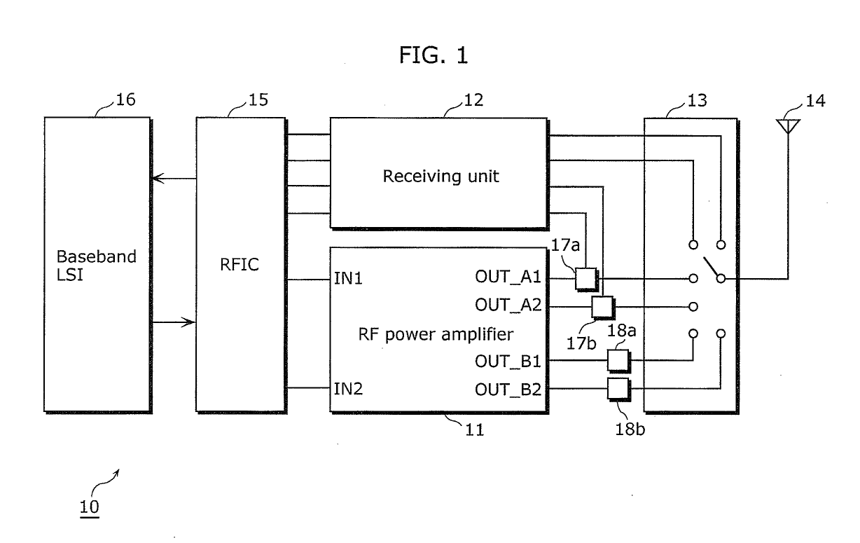

First, a wireless communication device to which a radio frequency (RF) power amplifier according to a first embodiment is applied will be described. FIG. 1 is a block diagram showing an example configuration of the wireless communication device.

A wireless communication device 10 shown in the figure corresponds to two frequency bands in UMTS mode (850 MHz band and 2 GHz band), GSM mode (900 MHz band) and DCS mode (1.8 GHz band). In other words, the wireless communication device 10 is compatible with four bands, three modes, for example. The wireless communication device 10 includes an RF power amplifier 11, a receiving unit 12, a switch 13, an antenna 14, an RFIC 15, and a baseband LSI 16.

The RF power amplifier 11 amplifies an RF signal output from the RFIC 15. The configuration of the RF power amplifier 11 will be described in detail later.

The receiving unit 12 receives, via the switch 13, a signal received by the antenna 14.

The switch 13 has one output terminal connected to the antenna and six input terminals connected to one of duplexers 17a and 17b, filters 18a and 18b, and the receiving unit 12, and passes a transmitted signal or a received signal by electrically connecting the output terminal and one of the input terminals. Note that two input terminals are connected to the receiving unit 12.

The antenna 14 transmits the signal propagated via the switch 13. In addition, the antenna 14 receives, as a received signal, a signal transmitted from another wireless communication device.

The RFIC 15 converts a baseband signal output from the baseband LSI 16, into an RF signal. In addition, the RFIC 15 demodulates the received signal received by the receiving unit 12 and supplies the demodulated signal to the baseband LSI 16.

The baseband LSI 16 performs, for example, signal processing such as compression and coding on an audio signal, so as to generate a baseband signal. The baseband LSI 16 supplies the generated baseband signal to the RFIC 15. In addition, the baseband LSI 16 performs signal processing such as sampling on the baseband signal input from the RFIC 15, so as to convert the baseband signal into an audio signal.

The duplexers 17a and 17b band-limit the signal in UMTS mode which is transmitted from the RF power amplifier 11, and transmit the band-limited signal from the antenna 14 via the switch 13. In addition, the duplexers 17a and 17b band-limit the signal from the switch 13 which is received by the receiving unit 12.

The filters 18a and 18b band-limit the signals in DCS mode and GSM mode transmitted from the RF power amplifier 11, and transmit the band-limited signal from the antenna 14 via the switch 13.

The configuration as described above allows the wireless communication device 10 shown in FIG. 1 to perform communication at four bands, three modes.

Next, an example of a detailed configuration of the RF power amplifier described above will be described.

The RF power amplifier according to the present embodiment is an RF power amplifier which amplifies RF signals of two frequency bands, and includes: a first power amplifying circuit which linearly amplifies a first RF signal of a first frequency band; a second power amplifying circuit which linearly amplifies a second RF signal of a second frequency band lower than the first frequency band; a third power amplifying circuit which nonlinearly amplifies a third RF signal of the first frequency band; and a fourth power amplifying circuit which nonlinearly amplifies a fourth RF signal of the second frequency band, and each of the power amplifying circuits (the first to fourth power amplifying circuits) includes: an input pad for wire bonding formed on a semiconductor substrate; an input line formed on the semiconductor substrate and having one end connected to the input pad; an amplifier formed on the semiconductor substrate and connected to the other end of the input line; an output line formed on the semiconductor substrate and having one end connected to the power amplifier; and an output pad formed on the semiconductor substrate and connected to the other end of the output line, the output pads of the first and second power amplifying circuits are disposed next to each other, the output pads of the third and fourth power amplifying circuits are disposed next to each other, the input lines of the respective power amplifying circuits do not cross each other on the semiconductor substrate, and the output lines of the respective power amplifying circuits do not cross each other on the semiconductor substrate.

With this, the RF power amplifier according to the present embodiment can improve isolation and operate at multiple bands and in multiple modes in each of the bands.

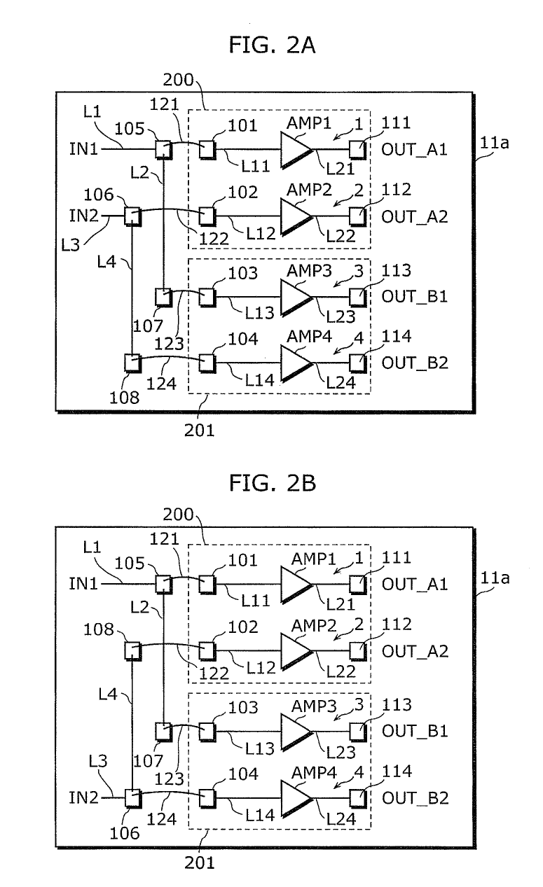

FIG. 2A is a diagram showing a circuit configuration and layout of the RF power amplifier according to the first embodiment, which represents an example of the RF power amplifier.

The RF power amplifier shown in the figure includes, on a board: chips 200 and 201 that are the semiconductor substrates in the present invention; the first to fourth connection pads 105 to 108, input terminals IN1 and IN2, and output terminals OUT_A1, OUT_A2, OUT_B1, and OUT_B2 (see FIG. 1).

Note that in the present embodiment it is sufficient to be compatible with at least two frequency bands and two frequency modes, respectively, and for convenience of explanation, an example described hereafter is assumed to be compatible with four bands, three modes, that is, DCS mode of 1.8 GHz band, GSM mode of 900 MHz band, UMTS mode of 2 GHz band, and UMTS mode of 850 MHz band. In other words, the RF power amplifier operates at a first frequency band in the high frequency range and a second frequency band in the low frequency range, operating in DCS mode and UMTS mode at the first frequency band and in GSM mode and UMTS mode at the second frequency band. That is, the RF power amplifier operates at multiple bands including the first frequency band and the second frequency band and in multiple modes in each of the bands (the first and second frequency bands).

The input terminal IN1 corresponds to the first input unit in the present invention, and signals of two frequency bands in the high frequency ranges, that is, RF signals of 1.8 GHz band in DCS mode and of 2 GHz band in UMTS mode are input into the input terminal IN1. In addition, formed on the board 11a are: a line L1 having one end connected to the input terminal IN1; a pad 105 connected to the other end of the line L1; a line L2 having one end connected to the pad 105; and a pad 107 connected to the other end of the line L2.

In addition, the input terminal IN2 corresponds to the second input unit in the present invention, and signals of the two frequency bands in the low frequency range, that is, RF signals of 900 MHz band in GSM mode and of 850 MHz band in UMTS mode are input into the input terminal IN2. In addition, formed on the board 11a are: a line L3 having one end connected to the input terminal IN2; a pad 106 connected to the other end of the line L3; a line L4 having one end connected to the pad 106; and a pad 108 connected to the other end of the line L4.

Note that the pads 105, 107, 106, and 108 correspond to the first, the second, the third, and the fourth connection pads in the present invention, respectively. In addition, the lines L1, L2, L3, and L4 correspond to the first, the second, the third, and the fourth connection lines in the present invention, respectively.

The chip 200 includes: a first power amplifying circuit 1 and a second power amplifying circuit 2 which require distortion characteristics, that is, linearly amplify the RF signal. The first power amplifying circuit 1 includes: a pad 101, an input line L11, a power amplifier AMP1, an output line L21, and an output pad 111. In addition, the second power amplifying circuit 2 includes: an input pad 102, an input line L12, a power amplifier AMP2, an output line L22, and an output pad 112. In addition, the pads 111 and 112 are disposed next to each other.

In addition, as with the chip 200, the chip 201 includes: a third power amplifying circuit 3 and a fourth power amplifying circuit 4 which do not require distortion characteristics, that is, nonlinearly amplify the RF signal. The third power amplifying circuit 3 includes: an input pad 103, an input line L13, a power amplifier AMP3, an output line L23, and an output pad 113. In addition, the fourth power amplifying circuit 4 includes: an input pad 104, an input line L14, a power amplifier AMP4, an output line L24, and an output pad 114. In addition, the pads 113 and 114 are disposed next to each other. The power amplifiers AMP3 and AMP4 operate in a saturation region of transistors.

The power amplifier AMP1, which has an input side connected to the pad 101 via the input line L11, amplifies the RF signal of 2 GHz band in UMTS mode that is input from the pad 101. Likewise, the power amplifier AMP2 amplifies an RF signal of 850 MHz band in UMTS mode that is input from the pad 102, the power amplifier AMP3 amplifies an RF signal of 1.8 GHz band in DCS mode that is input from the pad 103, and the power amplifier AMP4 amplifies an RF signal of 900 MHz band in GSM mode that is input from the pad 104. In addition, the power amplifier AMP1 has an output side connected to the pad 111, the power amplifier AMP2 has an output side connected to the pad 112, the power amplifier AMP3 has an output side connected to the pad 113, and the power amplifier AMP4 has an output side connected to the pad 114.

The pad 101 is electrically connected by wire bonding to the connection pad 105 formed on the board 11a via the wire 121. In other words, the wire 121 has one end bonded to the pad 101, and the other end bonded to the pad 105. Likewise, the pad 102 is electrically connected to the pad 106 via the wire 122, the pad 103 is electrically connected to the pad 107 via the wire 123, and the pad 104 is electrically connected to the pad 108 via the wire 124, respectively.

Note that the pads 101, 102, 103, and 104 correspond, respectively, to the first, the second, the third, and the fourth input pads in the present invention. In addition, the wires 121, 122, 123, and 124 correspond, respectively, to the first, the second, the third, and the fourth wires in the present invention.

In addition, the input line L11 connecting the pad 101 and the power amplifier AMP1 corresponds to the first input line in the present invention, the input line L12 connecting the pad 102 and the power amplifier AMP2 corresponds to the second input line in the present invention, the input line L13 connecting the pad 103 and the power amplifier AMP3 corresponds to the third input line in the present invention, and the input line L14 connecting the pad 104 and the power amplifier AMP4 corresponds to the fourth input line in the present invention. In addition, the power amplifiers AMP1, AMP2, AMP3, and AMP4 correspond, respectively, to the first, the second, the third, and the fourth power amplifiers in the present invention.

In addition, the output line L21 connecting the power amplifier AMP1 and the pad 111 corresponds to the first output line in the present invention, the output line L22 connecting the power amplifier AMP2 and the pad 112 corresponds to the second output line in the present invention, the output line L23 connecting the power amplifier AMP3 and the pad 113 corresponds to the third output line in the present invention, and the output line L24 connecting the power amplifier AMP4 and the pad 114 corresponds to the fourth output line in the present invention.

In addition, the pads 111, 112, 113, and 114 correspond, respectively, to the first, the second, the third, and the fourth output pads in the present invention.

Here, as shown in FIG. 2A, the output line L21 from the power amplifier AMP1 to the pad 111, the output line L22 from the power amplifier AMP2 to the pad 112, the output line L23 from the power amplifier AMP3 to the pad 113, and the output line L24 from the power amplifier AMP4 to the pad 114 do not cross each other. In addition, the input line L11 from the pad 101 to the power amplifier AMP1, the input line L12 from the pad 102 to the power amplifier AMP2, the input line L13 from the pad 103 to the power amplifier AMP3, and the input line L14 from the pad 104 to the power amplifier AMP4 do not cross each other.

Thus, since the lines propagating RF signals do not cross each other on the chips 200 and 201, it is possible to prevent deterioration of isolation of the RF signals between the pads 111 to 114, which is caused by parasitic capacitance between lines.

In addition, the pads 111, 112, 113, and 114 are connected, respectively, to the output terminals OUT_A1, OUT_A2, OUT_B1, and OUT_B2 (see FIG. 1). The output terminal OUT_A1 outputs the signal of 2 GHz band in UMTS mode, which has been amplified by the power amplifier AMP1. The output terminal OUT_A2, which is disposed next to the output terminal OUT_A1, outputs the signal of 850 MHz band in UMTS mode, which has been amplified by the power amplifier AMP2. The output terminal OUT_B1 outputs the signal of 1.8 GHz band in DCS mode, which has been amplified by the power amplifier AMP3. The output terminal OUT_B2, which is disposed next to the output terminal OUT_B1, outputs the signal of 900 MHz band in GSM mode, which has been amplified by the power amplifier AMP4.

An operation of the RF power amplifier according to the present embodiment will be described below.

Of the RF signals supplied from the RFIC 15 (see FIG. 1) to the RF power amplifier, the RF signals of 2 GHz band and 1.8 GHz band of frequency ranges relatively close to each other are input into the input terminal IN1, and the RF signals of 850 MHz band and 900 MHz band are input into the input terminal IN2, irrespective of modes.

The RF signal of 2 GHz band in UMTS mode, which is input into the input terminal IN1, is input into the pad 101 formed on the chip 200 from the pad 105 formed on the board 11a, via the wire 121. The RF signal of 2 GHz band in UMTS mode, which is input into the pad 101, is amplified by the power amplifier AMP1 via the input line L11 on the chip 200, to be output at the output terminal OUT_A1.

Likewise, the RF signal of 1.8 GHz band in DCS mode, which is input into the input terminal IN1, is input into the pad 103 formed on the chip 201 from the pad 107 formed on the board 11a, via the wire 123. The RF signal of 1.8 GHz band in DCS mode, which is input into the pad 103, is amplified by the power amplifier AMP3 via the input line L13 on the chip 201, to be output at the output terminal OUT_B1.

In addition, likewise, the RF signal of 900 MHz band in GSM mode, which is input into the input terminal IN2, is input into the pad 104 formed on the chip 201 from the pad 108 formed on the board 11a, via the wire 124. The RF signal of 900 MHz band in GSM mode, which is input into the pad 104, is amplified by the power amplifier AMP4 via the input line L14 on the chip 201, to be output at the output terminal OUT_B2.

In addition, likewise, the RF signal of 850 MHz band in UMTS mode, which is input into the input terminal IN2, is input into the pad 102 formed on the chip 200 from the pad 106 formed on the board 11a, via the wire 122. The RF signal of 850 MHz band in UMTS mode, which is input into the pad 102, is amplified by the power amplifier AMP2 via the input line L12 on the chip 200, to be output at the output terminal OUT_A2.

Here, as shown in FIG. 2A, the output terminal OUT_A1 for outputting the RF signal of 2 GHz band in UMTS mode and the output terminal OUT_A2 for outputting the RF signal of 850 MHz band in UMTS mode are disposed to be adjacent to each other or not to sandwich another output terminal in between, and the output terminal OUT_B1 for outputting the RF signal of 1.8 GHz band in DCS mode and the output terminal OUT_B2 for outputting the RF signal of 900 MHz band in GSM mode are disposed to be adjacent to each other or not to sandwich another output terminal in between.

In addition, the output line L21 from the power amplifier AMP1 to the pad 111, the output line L22 from the power amplifier AMP2 to the pad 112, the output line L23 from the power amplifier AMP3 to the pad 113, and the output line L24 from the power amplifier AMP4 to the pad 114 are disposed not to cross each other.

Accordingly, an output line from the power amplifier AMP1 to the output terminal OUT_A1, an output line from the power amplifier AMP2 to the output terminal OUT_A2, an output line from the power amplifier AMP3 to the output terminal OUT_B1, and an output line from the power amplifier AMP4 to the output terminal OUT_B2 do not cross each other.

In addition, the input line L11 from the pad 101 to the power amplifier AMP1, the input line L12 from the pad 102 to the power amplifier AMP2, the input line L13 from the pad 103 to the power amplifier AMP3, and the input line L14 from the pad 104 to the power amplifier AMP4 do not cross each other.

Accordingly, a sufficient isolation is secured for the RF signal of three bands, four modes (1.8 GHz band in DCS mode, 900 MHz band in GSM mode, 2 GHz band in UMTS mode, and 850 MHz band in UMTS mode), which is amplified by each of the power amplifiers (power amplifiers AMP1, AMP2, AMP3, and AMP4).

By thus laying out each of the output terminals (output terminals OUT_A1, OUT_A2, OUT_B1, and OUT_B2), as shown in FIG. 1, it is possible to collectively provide, on the board of the wireless communication device, the connection between the output terminal OUT_A1 and the duplexer 17a and the connection between the output terminal OUT_A2 and the duplexer 17b, thus allowing a compact and low-cost wireless communication device to be realized using a simpler layout. In addition, it is also possible to collectively provide, on the board of the wireless communication device, the connection between the output terminal OUT_B1 and the filter 18a and the connection between the output terminal OUT_B2 and the filter 18b, thus allowing a compact and low-cost wireless communication device to be realized using a simpler layout.

As described above, the RF power amplifier shown in FIG. 2A is an RF power amplifier which amplifies RF signals of two frequency bands and includes: a first power amplifying circuit 1 which linearly amplifies a first RF signal of a first frequency band; a second power amplifying circuit 2 which linearly amplifies a second RF signal of a second frequency band lower than the first frequency band; a third power amplifying circuit 3 which nonlinearly amplifies a third RF signal of the first frequency band; and a fourth power amplifying circuit 4 which nonlinearly amplifies a fourth RF signal of the second frequency band, and the power amplifying circuits 1 to 4 include, respectively: the input pads 101 to 104 for wire bonding which are formed on the chips 200 and 201; the input lines L11 to L14 formed on the chips 200 and 201 and having one end connected to the input pads 101 to 104, respectively; the power amplifiers AMP1 to AMP4 connected to the other end of the input lines L11 to L14, respectively; the output lines L21 to L24 formed on the chips 200 and 201 and having one end connected to the power amplifiers AMP1 to AMP4, respectively; and the output pads 111 to 114 formed on the chips 200 and 201 and connected to the other end of the output lines L21 to L24, respectively, and the first output pad 111 and the second output pad 112 are disposed next to each other, the third output pad 113 and the fourth output pad 114 are disposed next to each other, the input lines L11 to L14 do not cross each other on the chips 200 and 201, and the output lines L21 to L24 do not cross each other on the chips 200 and 201.

In other words, the plural lines from the power amplifiers AMP1 to AMP4 to the output terminals OUT_A1, OUT_A2, OUT_B1, and OUT_B2 do not cross each other. With this, the RF power amplifier can improve isolation at the output side of the power amplifiers AMP1 to AMP4, thus achieving improved isolation and enabling operation at multiple bands and in multiple modes in each of the bands. Specifically, since the power amplifiers AMP1 to AMP4 provide a large power output, the isolation at the output side of these power amplifiers AMP1 to AMP4 significantly contributes to the isolation of the RF power amplifier. In other words, by improving the isolation at the output side of the power amplifiers AMP1 to AMP4, it is possible to effectively improve the isolation of the RF power amplifier.

In addition, the input lines L11 to L14 from the input terminal IN1 and IN2 to the respective power amplifiers AMP1 to AMP4 do not cross each other on the chips 200 and 201. In other words, the lines from the pads 101 to 104 to the power amplifiers AMP1 to AMP4 do not cross each other. With this, it is possible to improve isolation at a crossing point of the signal paths at the input side of the power amplifiers AMP1 to AMP4.

Furthermore, the pads 101 to 104 are pads for wire bonding, and are connected via the wires 121 to 124, respectively. For example, the RF signal of 1.8 GHz in DCS mode, which is input from the input terminal IN1, is input into the power amplifier AMP3 through a signal path that is the line L2 connecting between the pads 105 and 107 on the board 11a, but the RF signal of 850 MHz in UMTS mode, which is input from the input terminal IN2, is input into a signal path that is the wire 122 provided from the pad 106 to the pad 102 so as to cross, above in the vertical direction, the line L2 formed on the board. Thus, compared to the case of crossing lines using not wires but, for example, a multilayer substrate or the like for crossing the lines in outer and inner layers of the multilayer substrate made up of dielectrics, the configuration allows a small spatial permittivity between the lines, and also allows securing a distance larger than an interlayer distance of the multilayer substrate. Accordingly, it is possible to improve isolation at a crossing point of the signal paths at the input side of the power amplifiers AMP1 to AMP4. In addition, in the configuration described above, the power amplifiers AMP1 and AMP2 formed on the chip 200 are used for RF power amplifiers compatible with UMTS mode, that is, requiring distortion characteristics, and the power amplifiers AMP3 and AMP4 formed on the chip 201 are used for RF power amplifiers compatible with DCS mode and GSM mode, that is, not requiring distortion characteristics. Thus, by forming, on separate semiconductor substrates, the power amplifiers AMP1 and AMP2 requiring distortion characteristics, that is, operating linearly, and the power amplifiers AMP3 and AMP4 not requiring distortion characteristics, that is, operating nonlinearly, it is possible to change the configuration of each of the semiconductor substrates according to the characteristics required of each of the power amplifiers, thus improving the radio frequency characteristics.

In addition, a line from the input terminal IN1 to the pad 103 is formed to be longer than the line from the input terminal IN1 to the pad 101 by including the line L2. Likewise, a line from the input terminal IN2 to the pad 104 is formed to be longer than the line from the input terminal IN2 to the pad 102 by including the line L4. With this, for the power amplifiers AMP1 and AMP2 that linearly operate, inductance by the length of the line L2 causes a phase shift, thus making it more difficult to perform impedance matching. However, this produces an advantageous effect of allowing the power amplifiers AMP3 and AMP4 which nonlinearly operate to require less accurate impedance matching for obtaining distortion characteristics as compared to the power amplifiers AMP1 and AMP2.

Note that the lines from the input terminals IN1 and IN2 to the pads 101 to 104 are not limited to the description above. For example, the line from the input terminal IN2 to the pad 102 may be longer than the line from the input terminal IN2 to the pad 104.

FIG. 2B is a diagram showing a configuration in which, the input terminal IN2 is disposed closer to the pad 104 in the configuration in FIG. 2A described above, and the pad 106 connected to the line L3 is connected to the pad 104. In addition, in the configuration, the other end of the line L4 having one end connected to the pad 106 is connected to the pad 108 disposed closer to the pad 102, and the pad 108 is connected to the pad 102.

With this configuration, an input impedance of the power amplifier AMP2 which amplifies the RF signal of 850 MHz band in UMTS mode has a phase caused to rotate by the length of the line L4 between the pads 106 and 108 on the board 11a, thus causing input impedance mismatching and deteriorating distortion characteristics and so on. On the other hand, for the power amplifier AMP4 which amplifies the RF signal of 900 MHz band in GSM mode, no loss is caused by line loss or phase shift by the length of the line L4, thus producing an advantageous effect of improving gain.

Note that the power amplifiers AMP1 to AMP4 may use a compound-semiconductor heterojunction bipolar transistor and a field-effect transistor.

In addition, in the first embodiment of the present invention, an example of the RF power amplifier compatible with four bands, three modes such as 1.8 GHz in DCS mode, 900 MHz band in GSM mode, 2 GHz band in UMTS mode, and 850 MHz band in UMTS mode has been described, but another frequency band or mode may be added.

Note that the configuration according to the present embodiment includes, on the board 11a, the pads 105, 106, 107, and 108 and the lines L1, L2, L3, and L4; however, the board 11a is not essential, and even when the board 11a does not include the pads 105, 106, 107, and 108 and the lines L1, L2, L3, and L4, it is possible to achieve an object of the present invention, so long as the configuration is such that the pads 101 to 104 are provided for wire bonding, and that the input lines L11 to L14 and the output lines L21 to L24 do not cross each other.

### Second Embodiment

An RF power amplifier according to a second embodiment differs from the RF power amplifier according to the first embodiment in that: in the present embodiment, the third input pad of the third power amplifying circuit is disposed closer to the third power amplifier than the first, the second, and the fourth input pads. In addition, one of the first and third input pads is directly bonded to the input terminal IN1, and the other of the first and third input pads is connected to the first or third input pad connected to the input terminal IN1. Likewise, one of the second and fourth input pads is directly bonded to the input terminal IN2, and the other of the second and fourth input pads is connected to the second or fourth input pad connected to the input terminal IN2. With this configuration, the wires bonded to the pads do not cross each other, thus improving isolation at a crossing point of the signal paths at the input side of the power amplifiers AMP1 to AMP4. The following description will be focused on the differences from the first embodiment.

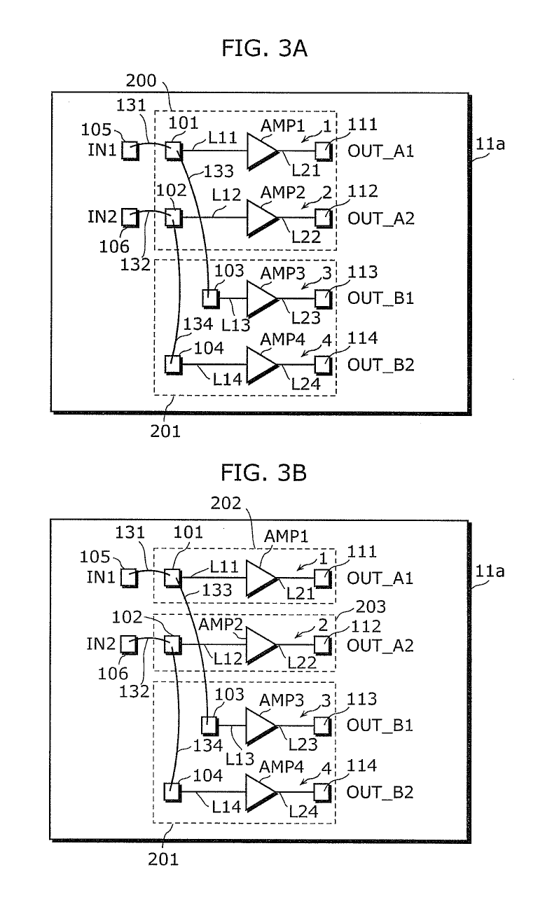

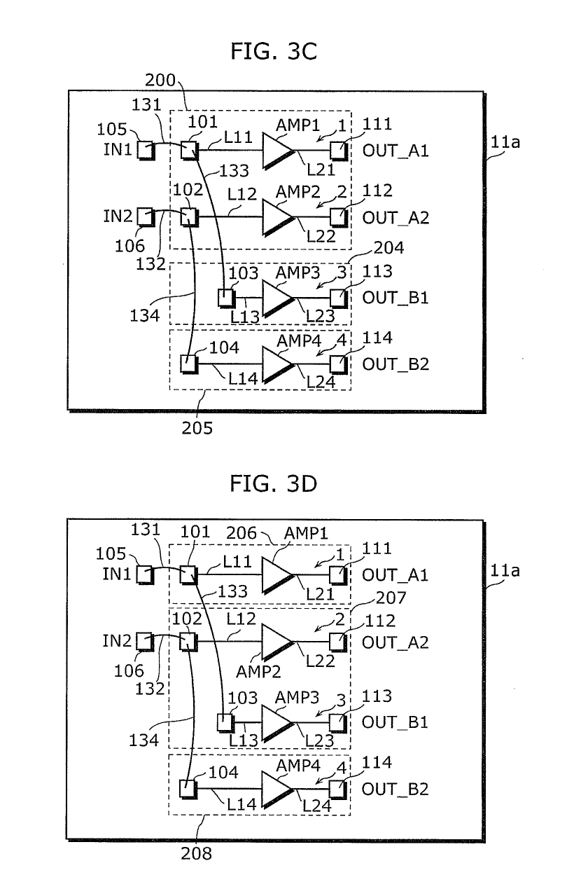

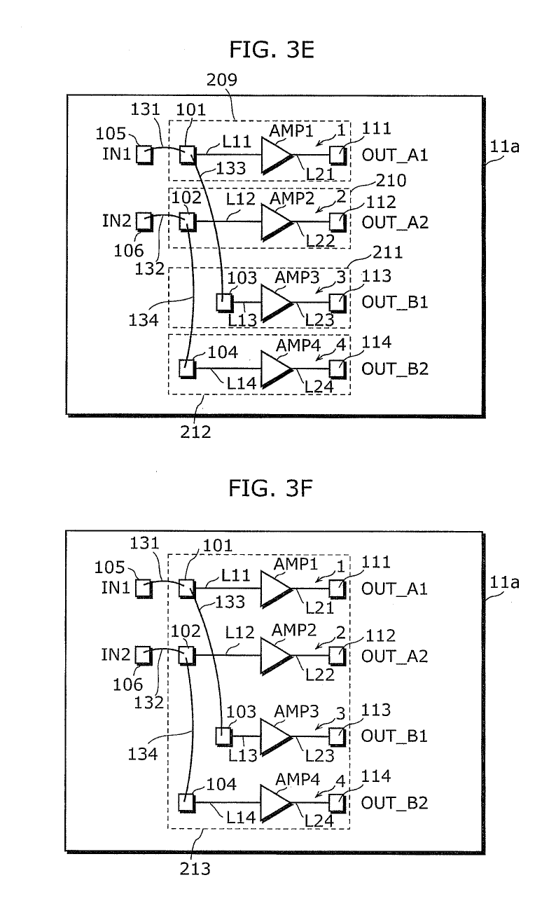

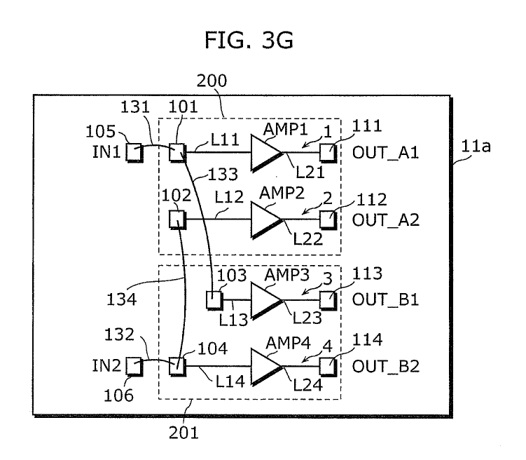

FIGS. 3A to 3G are diagrams each showing a circuit configuration of the RF power amplifier according to the second embodiment of the present invention and an actual layout of the circuit configuration on a board. Note that FIGS. 3B to 3F show the same structure as FIG. 3A except that: in FIGS. 3B to 3F, the power amplifier formed on the semiconductor device is either integrated or separately provided on plural semiconductor substrates.

FIG. 3A is a diagram showing an example circuit configuration and layout of the RF power amplifier according to the second embodiment. The RF power amplifier shown in the figure includes, on a board 11a: chips 200 and 201 that correspond to the semiconductor substrates in the present invention; a pad 105 connected to the input terminal IN1; a pad 106 connected to the input terminal IN2, and output terminals OUT_A1, OUT_A2, OUT_B1, and OUT_B2 (see FIG. 1).

In addition, the RF power amplifier according to the present embodiment also includes: a wire 131 having one end bonded to the pad 105 and the other end bonded to the pad 101 that is closest to the pad 105; a wire 133 having one end bonded to the pad 103 and the other end bonded to the pad 101 connected to the pad 105; a wire 132 having one end bonded to the pad 106 and the other end bonded to the pad 102 that is closest to the pad 106; and the wire 134 having one end bonded to the pad 104 and the other end bonded to the pad 102 connected to the pad 106.

Note that the wires 131, 133, 132, and 134 correspond, respectively, to the fifth, the sixth, the seventh, and the eighth wires in the present invention.

An RF signal of 2 GHz band in UMTS mode, which is input into the input terminal IN1, is input into the pad 101 formed on the chip 200 from the pad 105 formed on the board 11a, via the wire 131. The RF signal of 2 GHz band in UMTS mode, which is input into the pad 101, is amplified by the power amplifier AMP1 via the input line L11 on the chip 200, to be output at the output terminal OUT_A1.

An RF signal of 1.8 GHz band in DCS mode, which is input into the input terminal IN1, is input into the pad 103 formed on the chip 201 from the pad 101 formed on the chip 200, via the wire 133. The RF signal of 1.8 GHz band in DCS mode, which is input into the pad 103, is amplified by the power amplifier AMP3 via the input line L13 on the chip 201, to be output at the output terminal OUT_B1.

In addition, an RF signal of 850 MHz band in UMTS mode, which is input into the input terminal IN2, is input into the pad 102 via the wire 132. The RF signal of 850 MHz band in UMTS mode, which is input into the pad 102, is amplified by the power amplifier AMP2 via the input line L12 on the chip 200, to be output at the output terminal OUT_A2.

In addition, an RF signal of 900 MHz band in GSM mode, which is input into the input terminal IN2, is input into the pad 104 formed on the chip 201 from the pad 102 formed on the chip 200, via the wire 134. The RF signal of 900 MHz band in GSM mode, which is input into the pad 104, is amplified by the power amplifier AMP4 via the input line L14 on the chip 201, to be output at the output terminal OUT_B2.

Here, a feature is that the pad 103 on the semiconductor chip is disposed further inside the chip 201 than the other pads in a horizontal direction with respect to the drawing. In other words, the pad 103 that is the third input pad of the third power amplifying circuit 3 is disposed closer to the power amplifier AMP3 than the pads 101, 102, and 104 that are the first, the second, and the fourth input pads in the present invention.

With this configuration, the wires bonded to the pads do not cross each other, thus facilitating the layout of each wire. In addition, the wire 133 is provided to cross, above in the vertical direction, the input line L12 connecting the pad 102 and the power amplifier AMP2. Thus, compared to the case of crossing lines using not wires but, for example, a multilayer substrate or the like for crossing the lines in outer and inner layers of the multilayer substrate made up of dielectrics, the configuration allows a small spatial permittivity between the lines, and also allows securing a distance larger than an interlayer distance of the multilayer substrate. Accordingly, it is possible to improve isolation at a crossing point of the signal paths at the input side of the power amplifiers AMP1 to AMP4.

The configuration described above not only improves isolation at the input signal paths but also produces advantageous effects of downsizing by eliminating the need for areas for the pads 107 and 108 on the board 11a provided in the first embodiment, and for the lines connecting between the pads on the board 11a, and of suppressing insertion loss that occurs when the signal passes through the lines. In addition, regarding wire bonding, it is conventionally necessary to perform connection processing four times, that is, on the pads 105 and 101, the pads 106 and 102, the pads 107 and 103, and the pads 108 and 104; however, according to the present invention, it is only necessary to perform the processing two times, for example, by serially connecting the pads starting from the pad 105 to the pad 103 via the pad 101, and from the pad 106 to the pad 104 via the pad 102, thus increasing productivity and cost advantages.

The RF power amplifier shown in FIG. 3B includes a semiconductor substrate made up of the chips 201, 202, and 203, with the third power amplifying circuit 3 and the fourth power amplifying circuit 4 formed on the chip 201, and the first power amplifying circuit 1 formed on the chip 202, and the second power amplifying circuit 2 formed on the chip 203. That is, the configuration is such that: the power amplifier AMP1 is integrated on the chip 202, the power amplifier AMP2 is integrated on the chip 203, the power amplifiers AMP3 and AMP4 are integrated on the chip 201, and these are configured on the board 11a on which the pads 105 and 106 connected to the input terminals IN1 and IN2 are formed. In this case, the isolation of the power amplifiers AMP1 and AMP2 that are integrated on the chips 202 and 203, respectively, is improved.

The RF power amplifier shown in FIG. 3C includes a semiconductor substrate made up of the chips 200, 204, and 205, with the first power amplifying circuit 1 and the second power amplifying circuit 2 formed on the chip 200, and the third power amplifying circuit 3 formed on the chip 204, and the fourth power amplifying circuit 4 formed on the chip 205.

That is, the configuration is such that: the power amplifiers AMP1 and AMP2 are integrated on the chip 200, the power amplifier AMP3 is integrated on the chip 204, the power amplifier AMP4 is integrated on the chip 205, and these are configured on the board 11a on which the pads 105 and 106 connected to the input terminals IN1 and IN2 are formed. In this case, the isolation of the power amplifiers AMP3 and AMP4 that are integrated on the chips 204 and 205, respectively, is improved.

The RF power amplifier shown in FIG. 3D includes a semiconductor substrate made up of the chips 206, 207, and 208, with the second power amplifying circuit 2 and the third power amplifying circuit 3 formed on the chip 207, and the first power amplifying circuit 1 formed on the chip 206, and the fourth power amplifying circuit 4 formed on the chip 208.

That is, the configuration is such that: the power amplifier AMP1 is integrated on the chip 206, the power amplifiers AMP2 and AMP3 are integrated on the chip 207, the power amplifier AMP4 is integrated on the chip 208, and these are configured on the board 11a on which the pads 105 and 106 connected to the input terminals IN1 and IN2 are formed. In this case, the isolation of the power amplifiers AMP1, AMP2, AMP3, and AMP4 that are integrated on the chips 206, 207, and 208, respectively, is improved.

The RF power amplifier shown in FIG. 3E includes a semiconductor substrate made up of the chips 209, 210, 211, and 212, with the first power amplifying circuit 1 formed on the chip 209, the second power amplifying circuit 2 formed on the chip 210, the third power amplifying circuit 3 formed on the chip 211, and the fourth power amplifying circuit 4 formed on the chip 212.

That is, the configuration is such that: the power amplifier AMP1 is integrated on the chip 209, the power amplifier AMP2 is integrated on the chip 210, the power amplifier AMP3 is integrated on the chip 211, and the power amplifier AMP4 is integrated on the chip 212, and these are configured on the board 11a on which the pads 105 and 106 connected to the input terminals IN1 and IN2 are formed. In this case, the isolation of the power amplifiers AMP1, AMP2, AMP3, and AMP4 that are integrated on the chips 209, 210, 211, and 212, respectively, is improved.

The RF power amplifier shown in FIG. 3F includes a semiconductor substrate made up of the chip 213, with the first power amplifying circuit 1, the second power amplifying circuit 2, the third power amplifying circuit 3, and the fourth power amplifying circuit 4 formed on the single chip 213.

That is, the configuration is such that: the power amplifiers AMP1, AMP2, AMP3, and AMP4 are integrated on the chip 213, and these are configured on the board 11a on which the pads 105 and 106 connected to the input terminals IN1 and IN2 are formed. In this case, since all the power amplifiers AMP1 to AMP4 are integrated on the chip 213, the semiconductor chip needs to be mounted on the board 11a only once as compared to the cases of FIGS. 3A to 3E, thus producing a cost advantage, and it is also possible to expect downsizing by eliminating the need for a space between the semiconductor substrates that is expected to cover unevenness in placement at the time of mounting.

FIG. 3G shows an RF power amplifier in which the pad 106 connected to the input terminal IN2 is disposed closer to the pad 104 as compared to the RF power amplifier shown in FIG. 3A. In addition, the RF power amplifier according to the present embodiment also includes: a wire 132 having one end bonded to the pad 106 and the other end bonded to the pad 104 that is closest to the pad 106, and a wire 134 having one end bonded to the pad 104 and the other end bonded to the pad 102 connected to the pad 104.

By adapting this configuration, in the power amplifier AMP4 compatible with 900 MHz band in GSM mode, insertion loss or loss due to phase shift is not caused in the wire between the pads 102 and 104 on the semiconductor chip, thus producing an advantageous effect of improving gain.

In addition, since such a configuration allows increasing the distance between the input terminals IN1 and IN2, it is possible to improve isolation of the RF signals of the first and second frequency bands.

Note that the power amplifiers AMP1 to AMP4 may use a compound-semiconductor heterojunction bipolar transistor and a field-effect transistor.

In addition, in the second embodiment, an example of the RF power amplifier compatible with four bands, three modes, that is, 1.8 GHz in DCS mode, 900 MHz band in GSM mode, 2 GHz band in UMTS mode, and 850 MHz band in UMTS mode has been described, but another frequency band or mode may be added.

### Third Embodiment

An RF power amplifier according to a third embodiment differs from the RF power amplifier according to the second embodiment in that: in the present embodiment, the second and fourth input pads are directly connected to the input terminal IN2. With this configuration, the transmission path of the RF signal of 900 MHz band in GSM mode is shorter than the transmission path in the second embodiment as shown in FIG. 3A by a length of the wire between the pad 106 on the board 11a and the pad 104 on the chip 201, thus suppressing phase shift and reducing insertion loss or loss caused by impedance mismatching. The following description will be focused on the differences from the second embodiment.

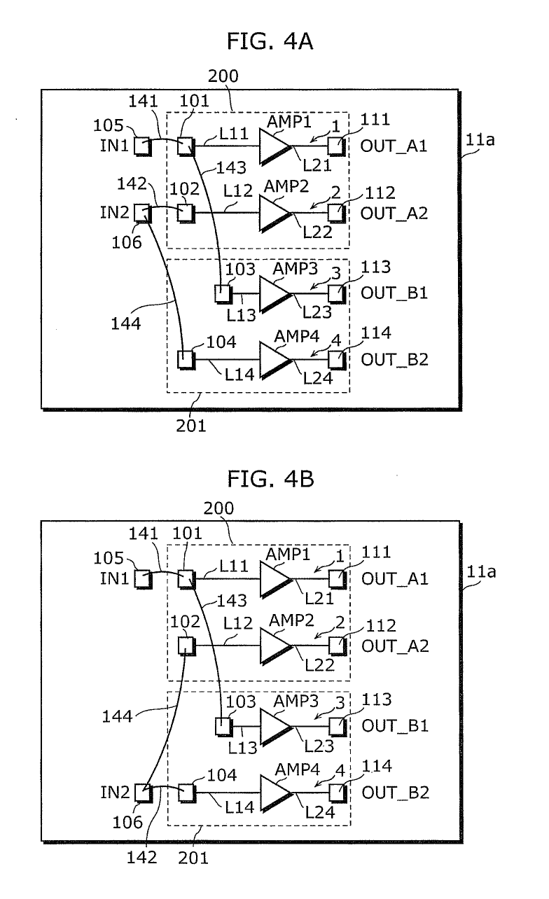

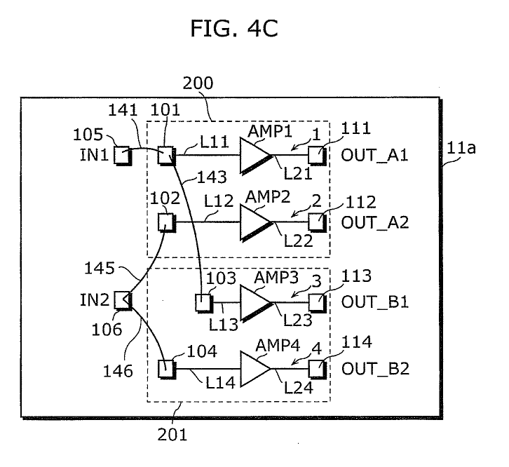

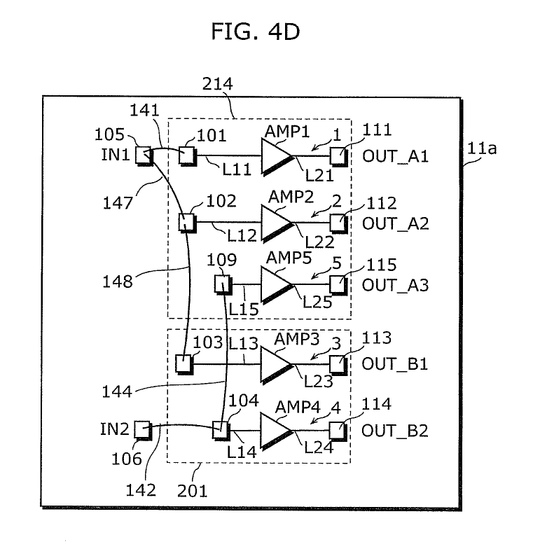

FIGS. 4A to 4D are diagrams each showing a circuit configuration of the RF power amplifier according to the third embodiment of the present invention and an actual layout of the circuit configuration on a board.

FIG. 4A is a diagram showing an example circuit configuration and layout of the RF power amplifier according to the third embodiment. As with the RF power amplifier shown in FIG. 3A, the RF power amplifier shown in the figure includes, on a board 11a: chips 200 and 201 that correspond to the semiconductor substrates in the present invention; a pad 105 connected to the input terminal IN1; a pad 106 connected to the input terminal IN2, and output terminals OUT_A1, OUT_A2, OUT_B1, and OUT_B2 (see FIG. 1).

In addition, the RF power amplifier according to the present embodiment also includes: a wire 141 having one end bonded to the pad 105 and the other end bonded to the pad 101 that is closest to the pad 105; a wire 143 having one end bonded to the pad 103 and the other end bonded to the pad 101 connected to the pad 105; a wire 142 having one end bonded to the pad 106 and the other end bonded to the pad 102 that is closest to the pad 106; and a wire 144 having one end bonded to the pad 104 and the other end directly bonded to the pad 106.

In addition, an RF signal of 900 MHz band in GSM mode, which is input into the input terminal IN2, is input into the pad 104 formed on the chip 201 from the pad 106 formed on the board 11a, via the wire 144 directly connected to the pad 104. The RF signal of 900 MHz band in GSM mode, which is input into the pad 104, is amplified by the power amplifier AMP4 via the input line L14 on the chip 201, to be output at the output terminal OUT_B2.

With this configuration, the transmission path of the RF signal of 900 MHz band in GSM mode is shorter than the transmission path in the second embodiment as shown in FIG. 3A by a length of the wire 142 between the pad 106 on the board 11a and the pad 102 on the chip 200, thus suppressing phase shift and reducing insertion loss and loss caused by impedance mismatching.

Compared to the RF power amplifying circuit shown in FIG. 4A, in the RF power amplifying circuit shown in FIG. 4B, the pad 106 connected to the input terminal IN2 is disposed closer to the pad 104, and the RF power amplifying circuit shown in FIG. 4B includes a wire 142 having one end bonded to the pad 106 and the other end bonded to the pad 104 that is closest to the pad 106, and a wire 144 having one end bonded to the pad 102 and the other end directly bonded to the pad 106.

That is, an RF signal of 850 MHz band in UMTS mode, which is input into the input terminal IN2, is input into the pad 102 from the pad 106 formed on the board 11a, via the wire 144 directly connected to the pad 102 on the chip 200. The RF signal of 850 MHz band in UMTS mode, which is input into the pad 102, is amplified by the power amplifier AMP2 via the input line L12 on the chip 200, to be output at the output terminal OUT_A2.

With this configuration, the transmission path of the RF signal of 850 MHz band in UMTS mode is rendered shorter than in the transmission path in the RF power amplifier shown in FIG. 4A by a length of the wire 142 between the pad 106 on the board 11a and the pad 104 on the chip 201, thus suppressing phase shift and reducing insertion loss and loss caused by impedance mismatching.

The RF power amplifying circuit shown in FIG. 4C has a feature that the pad 106 connected to the input terminal IN2 is disposed beside a horizontal axis of the pad 103 on the chip 201. That is, compared to the RF power amplifying circuit shown in FIGS. 4A and 4B, in the RF power amplifying circuit shown in FIG. 4C, the pad 106 is disposed equidistant from each of the pads 102 and 104, and the RF power amplifying circuit includes a wire 145 having one end bonded to the pad 106 and the other end bonded to the pad 102, and a wire 146 having one end bonded to the pad 106 and the other end bonded to the pad 104.

This configuration, when adapted, produces an advantageous effect of reducing input mismatching in the RF power amplifier of 900 MHz band in GSM mode than in the case of the RF power amplifier shown in FIG. 4A, and also reducing the input mismatching in the RF power amplifier of 850 MHz band in UMTS mode than in the case of the RF power amplifier shown in FIG. 4B.

Note that the power amplifiers AMP1 to AMP4 may use a compound-semiconductor heterojunction bipolar transistor and a field-effect transistor.

In addition, in the present embodiment, the pad 106 connected to the input terminal IN2 is directly connected to the pads 102 and 104, but the configuration may be such that the pad 105 connected to the input terminal IN1 is directly connected to the pads 101 and 103. In addition, the pad 105 may be disposed equidistant from each of the pads 101 and 103.

### Variation of Third Embodiment

In the third embodiment, an example of the RF power amplifier compatible with four bands, three modes of 1.8 GHz in DCS mode, 900 MHz band in GSM mode, 2 GHz band in UMTS mode, and 850 MHz band in UMTS mode has been described, but another frequency band or mode may be added. In this case, it is possible to add another power amplifying circuit as shown in FIG. 4D.

The RF power amplifier shown in FIG. 4D includes, in addition to the configuration of the RF power amplifier shown in FIG. 4A, a fifth power amplifying circuit 5 which includes: an input pad 109, an input line L15, a power amplifier AMP5, an output line L25, and an output pad 115. In addition, the RF power amplifier shown in the figure includes, on the board 11a: chips 214 and 201 that correspond to the semiconductor substrates in the present invention; a pad 105 connected to the input terminal IN1; a pad 106 connected to the input terminal IN2, and output terminals OUT_A1, OUT_A2, OUT_A3, OUT_B1, and OUT_B2.

The chip 214 includes pads 101, 102, 109, 111, 112, and 115, and power amplifiers AMP1, AMP2, and AMP5. In addition, the chip 201 includes pads 103, 104, 113, and 114, and power amplifiers AMP3 and AMP4. Here, the pads 109 and 104 are disposed closer to the power amplifiers 5 and 4, respectively, than the pads 101, 102, and 103.

In addition, the RF power amplifier shown in FIG. 4D also includes: a wire 141 having one end bonded to the pad 105 and the other end bonded to the pad 101 that is closest to the pad 105; a wire 147 having one end bonded to the pad 105 and the other end bonded to the pad 102; a wire 148 having one end bonded to the pad 103 and the other end bonded to the pad 102 connected to the pad 105; and a wire 142 having one end bonded to the pad 106 and the other end bonded to the pad 104 that is closest to the pad 106, and a wire 144 having one end connected to the pad 109 and the other end bonded to the pad 104 connected to the pad 106.

With the configuration shown in FIG. 4D, it goes without saying that the same advantageous effect as in FIGS. 4A to 4C above can be expected, and the wires bonded to the pads do not cross each other, thus facilitating the layout of each wire. In addition, it is possible to improve isolation at a crossing point of the signal paths at the input side of the power amplifiers AMP1 to AMP5.

Note that the power amplifiers AMP1 to AMP5 may use a compound-semiconductor heterojunction bipolar transistor and a field-effect transistor. In addition, the number of the semiconductor chips or the power amplifiers is not limited to the example described above, but may be changed in any manner according to the number of bands and modes.

### Fourth Embodiment

An RF power amplifier according to a fourth embodiment differs from the RF power amplifier according to the second embodiment in that: in the present embodiment, the third input pad of the third power amplifying circuit is disposed closer to the third power amplifier than the first, the second, and the fourth input pads, and the fourth input pad of the fourth power amplifying circuit is disposed at a predetermined position on a line extended from the input line of the third power amplifying circuit. With this configuration, since a larger area can be secured for the input lines that constitute the impedance matching circuit, it is possible to achieve a multistage matching circuit with improved performance, thus reducing loss in the RF signal caused by impedance mismatching or increasing the gain of the power amplifier. In addition, since this reduces the distance between each input unit and each input pad and accordingly reduces the length of the wire between the input pad and the wire, it is possible to reduce phase shift and insertion loss in the wire. The following description will be focused on the differences from the first embodiment.

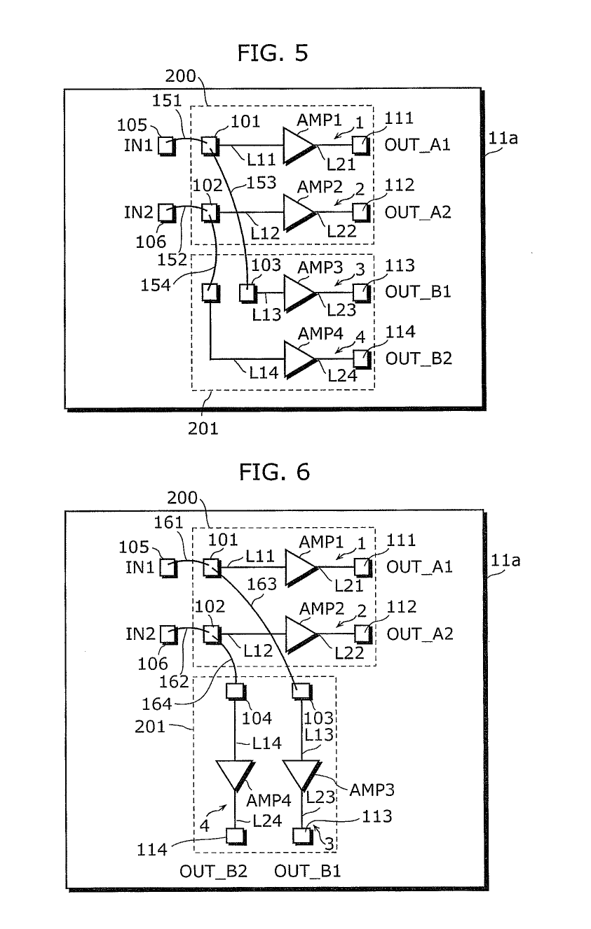

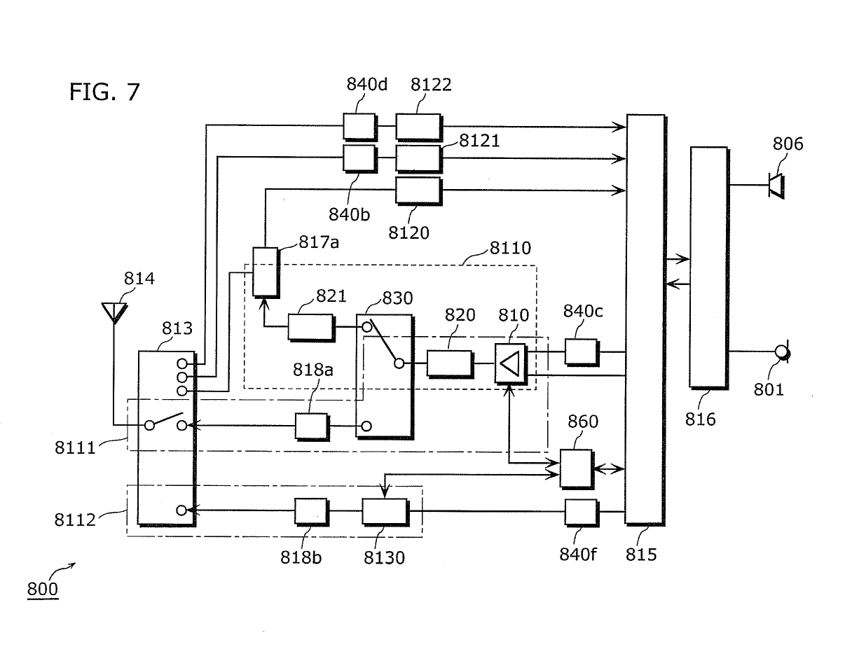

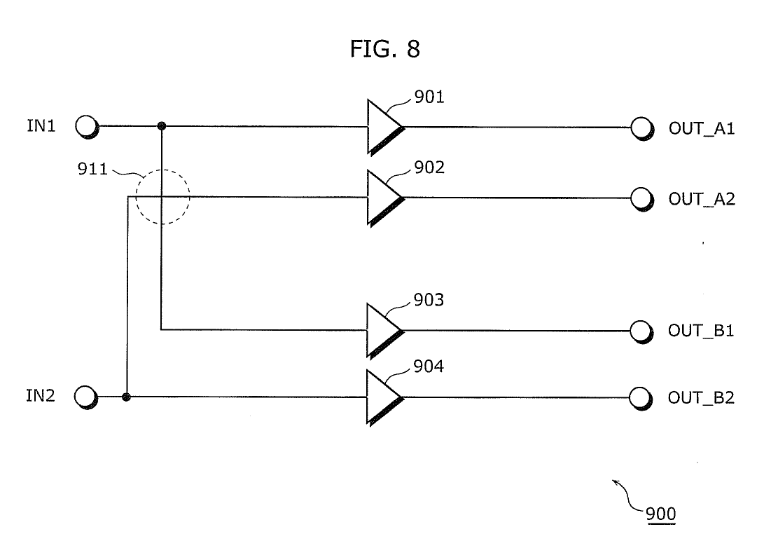

FIG. 5 is a diagram showing a circuit configuration of the RF power amplifier according to the fourth embodiment of the present invention and an actual layout of the circuit configuration on a board.

As shown in FIG. 5, the present embodiment has a feature that the pad 104 formed on the chip 201 in FIG. 3A is disposed beside a horizontal axis of the pad 103 on the chip 201. That is, the pad 103 that is the third input pad of the third power amplifying circuit 3 is disposed closer to the power amplifier AMP3 than the pads 101, 102, and 104 that correspond, respectively, to the first, the second, and the fourth input pads in the present invention, and the pad 104 next to the pad 103 is disposed on a line extended from the input line L13 connected to the power amplifier AMP3 and is also disposed at a position such that a distance from the power amplifier AMP3 to the pad 104 is equal to a distance from the first power amplifier AMP1 to the pad 101. Then, the input line L14 is vertically bent from the power amplifier AMP4, to be connected to the pad 104.

In addition, the RF power amplifier according to the present embodiment also includes: a wire 151 having one end bonded to the pad 105 and the other end bonded to the pad 101 that is closest to the pad 105; a wire 153 having one end bonded to the pad 103 and the other end bonded to the pad 101 connected to the pad 105; a wire 152 having one end bonded to the pad 106 and the other end bonded to the pad 102 that is closest to the pad 106; and a wire 154 having one end bonded to the pad 104 and the other end bonded to the pad 102 connected to the pad 106.

An RF signal of 900 MHz band in GSM mode, which is input into the input terminal IN2, is input into the pad 104 formed on the chip 201 from the pad 102 formed on the chip 200, via the wire 154. The RF signal of 900 MHz band in GSM mode, which is input into the pad 104, is amplified by the power amplifier AMP4 via the line on the chip 201, to be output at the output terminal OUT_B2.

With this configuration, the RF amplifying circuit according to the present embodiment allows securing a wider path between the pad 104 on the chip 201 and the power amplifier AMP4 compatible with 900 MHz band in GSM mode than the second embodiment as shown in FIG. 3A. In other words, since a larger area can be secured for the input line L14 that is the impedance matching circuit for the RF signal of 900 MHz band in GSM mode, it is possible to achieve a multistage matching circuit with improved performance, thus reducing loss caused by impedance mismatching in the RF signal of 900 MHz band in GSM mode, or increasing the gain of the power amplifier. In addition, since this reduces the distance between the pads 102 and 104 and accordingly reduces the length of the wire between the pads 102 and 104, thus reducing phase shift and insertion loss in the wire.

Note that in the present embodiment, the configuration is such that the third input pad 103 is disposed closer to the power amplifier AMP3, and the fourth input pad 104 adjacent to the third input pad 103 is disposed at the predetermined position on the line extended from the input line L13 of the third power amplifying circuit 3, but a pad other than the third and fourth pads may also be disposed in such a manner.

### Fifth Embodiment

An RF power amplifier according to a fifth embodiment differs from the RF power amplifier according to the second embodiment in that: in the present embodiment, the third and fourth power amplifying circuits are rotated to be disposed at a predetermined angle with respect to the first and the second power amplifying circuits. With this configuration, it is possible to downsize the RF power amplifier. In addition, by forming a desired RF power amplifying circuit on the same or a different semiconductor substrate, it is possible to reduce phase shift, insertion loss, or loss caused by impedance mismatching, thus forming the RF power amplifier with improved isolation. The following description will be focused on the differences from the second embodiment.

FIG. 6 is a diagram showing a circuit configuration of the RF power amplifier according to the fifth embodiment of the present invention and an actual layout of the circuit configuration on a board.

As shown in FIG. 6, the present embodiment has a feature that: as compare to the RF power amplifier shown in FIG. 3A, the chip 201 is rotated 90 degrees in a clockwise direction to be disposed.

In addition, the RF power amplifier according to the present embodiment also includes: a wire 161 having one end bonded to the pad 105 and the other end bonded to the pad 101 that is closest to the pad 105; a wire 163 having one end bonded to the pad 103 and the other end bonded to the pad 101 connected to the pad 105; a wire 162 having one end bonded to the pad 106 and the other end bonded to the pad 102 that is closest to the pad 106; and a wire 164 having one end bonded to the pad 104 and the other end bonded to the pad 102 connected to the pad 106.

The second embodiment described earlier has a feature that the pad 103 on the chip 201 is disposed further inside the chip 201 than the other pads, that is, disposed closest to the power amplifier AMP3, but this case has resulted in narrowing the input path on the chip 201 for the power amplifier AMP3 compatible with 1.8 GHz in DCS mode, that is, reducing size of the area for the input matching circuit formed between the pad 103 and the power amplifier AMP3. On the other hand, by disposing the chip 201 as in the present embodiment, the wire 163 connecting the pads 101 and 103 and the wire 164 connecting the pads 102 and 104 do not cross each other, so that the pad 103 need not be disposed closer to the power amplifier AMP3, and thus a larger area can be secured for the impedance matching circuit, thus achieving a multistage matching circuit with improved performance and reducing the loss caused by impedance mismatching or increasing the gain of the power amplifier.

In addition, by disposing the chip 201 as shown in the present embodiment, the distance between the pads 102 and 104 is reduced, with the length of the bond wire between the pads 102 and 104 reduced accordingly, thus producing another advantageous effect of reducing phase shift and insertion loss in the bond wire.

Note that in the present embodiment, the chip 201 is rotated in a clockwise direction, but it goes without saying that the same advantageous effect can be produced by rotating the chip 200 in an anticlockwise direction.

Thus far, the RF power amplifier according to embodiments of the present invention has been described with reference to the first to the fifth embodiments, but the present invention is not limited to these embodiments. Those skilled in the art will readily appreciate that many modifications are possible in the exemplary embodiments without departing from the novel teachings and advantages of this invention. Accordingly, all such modifications are intended to be included within the scope of this invention.

For example, in the descriptions above, the output terminals OUT_A1 and OUT_A2 connected to the duplexer have been disposed next to each other, but may be disposed at a distance as long as other terminals connected to the filters (for example, output terminals OUT_B1 and OUT_B2) are not disposed between the output terminals OUT_A1 and OUT_A2.

Although only some exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

### INDUSTRIAL APPLICABILITY

An RF power amplifier according to the present invention is appropriate for multiband and multimode performance, and is applicable to a mobile terminal device and so on.

What is claimed is:

1. A radio frequency power amplifier which amplifies radio frequency signals of two frequency bands, said radio frequency power amplifier comprising:
a first power amplifying circuit which linearly amplifies a first radio frequency signal of a first frequency band;
a second power amplifying circuit which linearly amplifies a second radio frequency signal of a second frequency band lower than the first frequency band;
a third power amplifying circuit which nonlinearly amplifies a third radio frequency signal of the first frequency band; and
a fourth power amplifying circuit which nonlinearly amplifies a fourth radio frequency signal of the second frequency band,
wherein said first power amplifying circuit includes:
a first input pad for wire bonding formed on a semiconductor substrate;
a first input line formed on said semiconductor substrate and having one end connected to said first input pad;
a first power amplifier formed on said semiconductor substrate and connected to the other end of said first input line;
a first output line formed on said semiconductor substrate and having one end connected to said first power amplifier; and
a first output pad formed on said semiconductor substrate and connected to the other end of said first output line,
said second power amplifying circuit includes:
a second input pad for wire bonding formed on said semiconductor substrate;
a second input line formed on said semiconductor substrate and having one end connected to said second input pad;
a second power amplifier formed on said semiconductor substrate and connected to the other end of said second input line;
a second output line formed on said semiconductor substrate and having one end connected to said second power amplifier; and
a second output pad formed on said semiconductor substrate and connected to the other end of said second output line,
said third power amplifying circuit includes:
a third input pad for wire bonding formed on said semiconductor substrate;
a third input line formed on said semiconductor substrate and having one end connected to said third input pad;
a third power amplifier formed on said semiconductor substrate and connected to the other end of said third input line;
a third output line formed on said semiconductor substrate and having one end connected to said third power amplifier; and
a third output pad formed on said semiconductor substrate and connected to the other end of said third output line,
said fourth power amplifying circuit includes:
a fourth input pad for wire bonding formed on said semiconductor substrate;
a fourth input line formed on said semiconductor substrate and having one end connected to said fourth input pad;
a fourth power amplifier formed on said semiconductor substrate and connected to the other end of said fourth input line;
a fourth output line formed on said semiconductor substrate and having one end connected to said fourth power amplifier; and
a fourth output pad formed on said semiconductor substrate and connected to the other end of said fourth output line,
said first and second output pads are disposed next to each other,
said third and fourth output pads are disposed next to each other,
said first to fourth input lines do not cross each other on said semiconductor substrate, and
said first to fourth output lines do not cross each other on said semiconductor substrate.

2. The radio frequency power amplifier according to claim 1,
wherein said first input pad is wire-bonded to a first input unit which is provided on a board that is to be mounted with said radio frequency power amplifier and into which the first and third radio frequency signals are input,
said second input pad is wire-bonded to a second input unit which is provided on said board and into which the second and fourth radio frequency signals are input,
said third input pad is wire-bonded to said first input unit, and
said fourth input pad is wire-bonded to said second input unit.

3. The radio frequency power amplifier according to claim 1, comprising:
a board; and
said semiconductor substrate to be mounted on said board,
wherein said board includes:
a first line having one end connected to said first input unit;
a first connection pad connected to the other end of said first line;
a second line having one end connected to said first connection pad;
a second connection pad connected to the other end of said second line;
a third line having one end connected to said second input unit;
a third connection pad connected to the other end of said third line;
a fourth line having one end connected to said third connection pad; and
a fourth connection pad connected to the other end of said fourth line, and
said radio frequency power amplifier further comprises:
a first wire having one end bonded to said first input pad and the other end bonded to one of said first and second connection pads that is closer to said first wire;
a second wire having one end bonded to said second input pad and the other end bonded to one of said third and fourth connection pads that is closer to said second wire;
a third wire having one end bonded to said third input pad and the other end bonded to the other of said first and second connection pads that is closer to said third wire; and
a fourth wire having one end bonded to said fourth input pad and the other end bonded to the other of said third and fourth connection pads that is closer to said fourth wire.

4. The radio frequency power amplifier according to claim 2, comprising:
a fifth wire having one end bonded to said first input unit and the other end bonded to one of said first and third input pads that is closer to said first input unit; and
a sixth wire having one end bonded to the other of said first and third input pads and the other end bonded to said one of said first and third input pads connected to said first input unit.

5. The radio frequency power amplifier according to claim 2, comprising:
a seventh wire having one end bonded to said second input unit and the other end bonded to one of said second and fourth input pads that is closer to said second input unit; and
an eighth wire having one end bonded to the other of said second and fourth input pads and the other end bonded to said one of said second and fourth input pads connected to said second input unit.

6. The radio frequency power amplifier according to claim 2, comprising:
a fifth wire having one end bonded to said first input unit and the other end bonded to one of said first and third input pads that is closer to said first input unit;
a sixth wire having one end bonded to the other of said first and third input pads and the other end bonded to said one of said first and third input pads connected to said first input unit;
a seventh wire having one end bonded to said second input unit and the other end bonded to one of said second and fourth input pads that is closer to said second input unit; and
an eighth wire having one end bonded to the other of said second and fourth input pads and the other end bonded to said one of said second and fourth input pads connected to said second input unit.

7. The radio frequency power amplifier according to claim 1,
wherein at least one of said first to fourth input pads is disposed closer to a corresponding one of said first to fourth power amplifiers than the others of said first to fourth input pads.

8. The radio frequency power amplifier according to claim 7,
wherein one of said first to fourth input pads that is next to said at least one of said first to fourth input pads that is disposed closer to said corresponding one of said first to fourth power amplifiers is disposed at a predetermined position on a line extended from said input line connected to said corresponding one of said first to fourth power amplifiers.

9. The radio frequency power amplifier according to claim 2,
wherein said first input unit is disposed equidistant from each of said first and third input pads.

10. The radio frequency power amplifier according to claim 2,
wherein said second input unit is disposed equidistant from each of said second and fourth input pads.

11. The radio frequency power amplifier according to claim 1,
wherein said semiconductor substrate includes a first semiconductor chip and a second semiconductor chip,
said first and second power amplifying circuits are formed on said first semiconductor chip, and
said third and fourth power amplifying circuits are formed on said second semiconductor chip.

12. The radio frequency power amplifier according to claim 1,
wherein said semiconductor substrate includes a first semiconductor chip, a second semiconductor chip, and a third semiconductor chip,
said third and fourth power amplifying circuits are formed on said first semiconductor chip,
said first power amplifying circuit is formed on said second semiconductor chip, and
said second power amplifying circuit is formed on said third semiconductor chip.

13. The radio frequency power amplifier according to claim 1,
wherein said semiconductor substrate includes a first semiconductor chip, a second semiconductor chip, and a third semiconductor chip,
said first and second power amplifying circuits are formed on said first semiconductor chip,
said third power amplifying circuit is formed on said second semiconductor chip, and
said fourth power amplifying circuit is formed on said third semiconductor chip.

14. The radio frequency power amplifier according to claim 1,
wherein said semiconductor substrate includes a first semiconductor chip, a second semiconductor chip, and a third semiconductor chip,
said second and third power amplifying circuits are formed on said first semiconductor chip,
said first power amplifying circuit is formed on said second semiconductor chip, and
said fourth power amplifying circuit is formed on said third semiconductor chip.

15. The radio frequency power amplifier according to claim 1,
wherein said semiconductor substrate includes four semiconductor chips, and
said first to fourth power amplifying circuits are formed in said semiconductor chips different from each other.

16. The radio frequency power amplifier according to claim 1,
wherein said semiconductor substrate is a semiconductor chip.

17. The radio frequency power amplifier according to claim 1,
wherein said third and fourth power amplifying circuits are rotated to be disposed at a predetermined angle with respect to said first and second power amplifying circuits.
